(19) United States
(12) Patent Application Publication
(10) Pub. No.: US 2026/0271773 A1
(43) Pub. Date: Sep. 10, 2026

(54) MEMORY PACKAGES WITH SELF-TUNING PROTECTIVE MATERIAL

(71) Applicant: Micron Technology, Inc., Boise, ID (US)

(72) Inventors: Chong Leong Gan, Taichung (TW); Min-Hua Chung, Taichung (TW); Mohamad Zainudeen Bin Moideen, Sungai Petani (MY)

(21) Appl. No.: 19/553,997

(22) Filed: Mar. 2, 2026

Related U.S. Application Data
(60) Provisional application No. 63/766,482, filed on Mar. 4, 2025.

(51) Int. Cl. H10W 74/10; H10W 74/47; H10W 90/24; H10B 80/00

(52) U.S. Cl. CPC H10W 74/121; H10W 74/473; H10W 90/24; H10B 80/00

(57) ABSTRACT

Systems, methods, and apparatus are provided for a more reliable memory package. A particular memory package can comprise a substrate and a plurality of memory layers, the memory layers can be surrounded by an encapsulant. The encapsulant can have a number of surfaces coated in a self-tunable compound. The self-tunable compound can have a reduced elastic modulus at high temperatures resulting in decreased stress on components at higher temperatures.

### PRIORITY INFORMATION

This application claims the benefit of U.S. Provisional Application Number 63/766,482, filed on Mar. 4, 2025, the contents of which are incorporated herein by reference.

### TECHNICAL FIELD

The present disclosure relates generally to integrated circuits, and more particularly to memory packages with self-tuning protective material.

### BACKGROUND

A memory apparatus can include memory cells arranged in layers. These layers can be arranged in a package protecting the memory cells while leaving electrically conductive contacts exposed. The memory package can be connected to a printed circuit board allowing other components to access data stored in the memory or write data do the cells of the memory package through the electrically conductive contacts.

### BRIEF DESCRIPTION OF THE DRAWINGS

FIG. 1 illustrates an example memory package including a field’s metal hybrid elastomer (FMHE) coating an encapsulant in accordance with a number of embodiments of the present disclosure.

FIG. 2 illustrates another memory package including a FMHE coating on an encapsulant in accordance with a number of embodiments of the present disclosure.

FIG. 3 illustrates yet another example memory package including a FMHE coating an encapsulant and/or included in an underfill layer in accordance with a number of embodiments of the present disclosure.

FIG. 4 illustrates yet another example memory package including a FMHE coating an encapsulant and/or included in an underfill layer in accordance with a number of embodiments of the present disclosure.

FIG. 5 illustrates an underfill layer including a FMHE in accordance with a number of embodiments of the present disclosure.

FIG. 6 illustrates a memory system utilizing a memory package in accordance with a number of embodiments of the present disclosure.

### DETAILED DESCRIPTION

Embodiments of the present disclosure describe a memory package with a protective coating. The memory package can be used in an integrated circuit, for instance. The memory package can be used in personal computers, work stations, handheld electronics, vehicle dashboard electronics, and other electronics. In some embodiments, the memory package can be utilized in high memory, low latency applications. For example, smart devices such as phones or vehicles. The protective coating may be a self-tunable material, changing its physical properties (e.g., elastic modulus) when exposed to different environmental stimulus.

Electronic devices such as smart phones have increasing processing power, increasing speed, and decreasing size. One result of these changes is an increase in operating temperature of components of the device. Increases in temperature, due to normal operation or otherwise, can result in degradation of the connections between components and the components themselves. The degradation resulting from temperature changes may be caused by components expanding as they heat up and contracting as they cool down. The expanding and contracting of components may apply a stress on the components, any case containing the components, and the connections between components. A stress applied to the components may cause them to crack, warp, delaminate, and lose contact at connection points. These defects are more likely to occur when the device is repeatedly placed under that stress. Also, devices subject to shock or vibrations are more likely to develop a defect if that device is also experiencing a stress resulting from high operation temperatures. Some embodiments of the present disclosure may alleviate the stress resulting from high temperatures on memory components by coating the outside of these components in a self-tunable compound that will have a reduced elastic modulus at high temperatures but retain a high elastic modulus at lower temperatures such as room temperature.

In some embodiments, the self-tunable compound may coat a surface of an encapsulant of a memory package. As used herein, the term “package” generally refers to a collection of one or more memory devices on a substrate surrounded by an encapsulant. The encapsulant may be an epoxy mold compound (EMC) and may leave a surface of the substrate exposed. The exposed surface of the substrate may have areas designed to make electrical contact with other electrical components such as a printed circuit board (PCB). Contact between the substrate of a memory package and a PCB may be made by solder joints which may leave a gap between the substrate and the PCB except where the solder joints are. The gap between the substrate and the PCB may be filled with an underfill material. In some embodiments the underfill material includes the self-tunable compound. In some embodiments, the self-tunable compound may coat all surfaces of the encapsulant that would otherwise be exposed. As used herein, the term “coat” or “coating” generally refers to a material covering one or more surfaces of another material.

A self-tunable compound coating a memory package may alleviate stress resulting from increased temperatures of the memory package. The self-tunable compound may reduce stress by maintaining a rigid form until reaching a critical temperature at which the self-tunable compound has a reduced elastic modulus. The reduced elastic modulus allows the self-tunable compound to expand with the heated components without causing much stress.

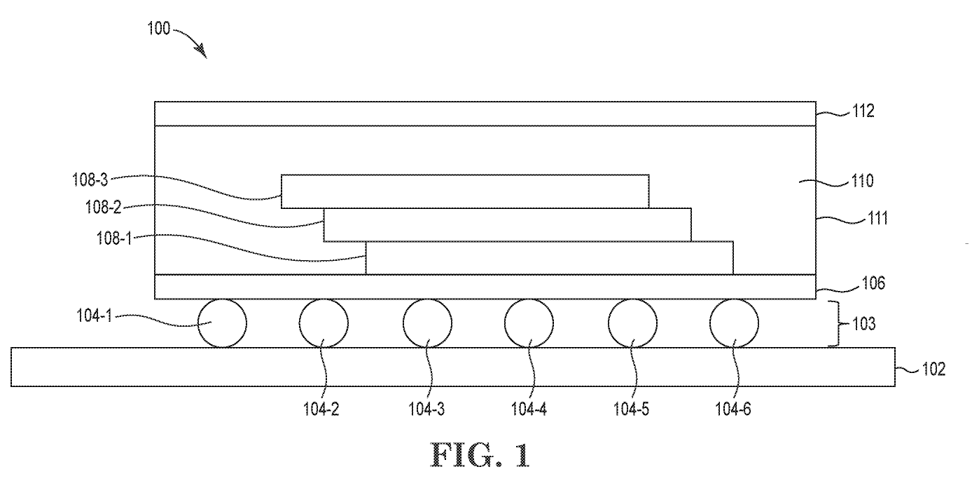

In a number of embodiments of the present disclosure (e.g., embodiments described in association with FIGS. 1-5), The self-tunable compound may be a hybrid elastomer with low melting point solids dispersed throughout it. The low melting point solids may be metal or metal alloys. One metal alloy that may be used is field’s metal, an alloy of indium, bismuth, and tin, or any combination thereof. In embodiments of this disclosure, the self-tunable compound may be a field’s metal hybrid elastomer (FMHE) that is a polydimethylsiloxane (PDMS) matrix with field’s metal microparticles and spiked nickel microparticles dispersed in the PDMS matrix. For example, the low melting point solids can be microparticles, such as field’s metal microparticles, with a size (e.g., diameter) ranging from 10 micrometers to 20 micrometers. The Spiked nickel particles may be a different size from the low melting point solids (e.g. fields metal microparticles). The spiked nickel microparticles may be smaller or larger than the low melting point solids. The mass ratio of the spiked nickel particles to the PDMS matrix may be between 0.5 and 3 (e.g. ratios of 1:2 to 3:1 by mass).

As described herein, a self-tunable compound, such as a FMHE material, can have self-tuning properties. Alternatively speaking, the self-tunable compound can be capable of (e.g., configured to) autonomously adjust its physical properties (e.g., elastic modulus) in response to an external stimuli. For example, the FMHE material may tune the elastic modulus of the FMHE material when exposed to temperatures above 80 degrees Celsius. At temperatures below 80 degrees Celsius the field’s metal microparticles in the FMHE can cause the elastic modulus of the FMHE material to be higher by resisting movement or changes in shape. Above 80 degrees Celsius the field’s metal microparticles in the FMHE material may change phase from solid to liquid and therefore contribute less to the stiffness of the material. The change in elastic modulus of the FMHE material may be affected by the concentration of field’s metal microparticles and spiked nickel microparticles. Other hybrid elastomers, or elastomer materials with microparticles formed of solids other than field’s metal, may provide a similar self-tuning effect depending on the melting point of the other solids forming the microparticles.

FIG. 1 illustrates an example memory package 100 including a FMHE 112 an encapsulant 110 in accordance with a number of embodiments of the present disclosure. The memory package 100 has a substrate 106 on which a number of memory layers 108-1, 108-2, 108-3 (collectively referred to as memory layers 108) are formed. Although three memory layers 108-1, 108-2, 108-3 and six interconnects 104-1, …, 104-6 are respectively illustrated in FIG. 1, embodiments are not limited to a particular amount of memory layers and/or interconnects the memory package 100 can include or be coupled to.

Each layer of memory layers 108 can be a memory die, which can individually correspond to an array of memory cells (e.g., DRAM, NAND, etc.). The memory layers 108 can be alternatively referred to as a “stack” of memory dies or layers. In some embodiments, one of the memory layers 108 (e.g., the memory layer 108-1) can be a base die on which the other memory layers 108 (e.g., the memory layers 108-2, 108-3 and alternatively referred to as core dies) are stacked. As used herein, the term “base die” refers to the foundational layer in a stacked memory system, serving as the interface between the stacked memory dice and external components. For example, the base die can include control circuitry, such as memory controllers or logic for managing data flow, power distribution, and communication within the memory stack and with external devices. As used herein, the term “core die” refers to an individual memory die (that is not a base die) within a stacked memory system, responsible for storing and processing data. Core dies can work collaboratively with other core dies in the stack to achieve high memory density and bandwidth, and they are interconnected via through-silicon vias (TSVs) for seamless communication within the memory system.

As shown in FIG. 1, the memory layers 108 are surrounded by an encapsulant 110 that, in combination with the substrate 106, covers the entirety of the memory layers 108. The encapsulant 110 is coated in a protective material 112 that covers an exposed area of the encapsulant. Although embodiments are not so limited, the encapsulant 110 can be an organic material layer, an epoxy mold compound (EMC), etc. In some embodiments, the memory package 100 may have exposed surfaces 111 of the encapsulant 110 not covered by the protective material 112. For example, as shown in FIG. 1, a layer comprising FMHE coating 112 can be formed (e.g., deposited) on a top side (e.g., surface) of the encapsulant 110 that is opposite to the surface of the encapsulant 110 that is in contact with the substrate 106. This coating process leaves certain surfaces of the encapsulant 110, such as its side surfaces 111, uncovered and exposed to the external environment. As used herein, the term “side surfaces” of the encapsulant 110 refers to those surfaces of the encapsulant 110 that extend vertically or at an angle between the top surface (e.g., where the FMHE coating 112 is deposited) and the bottom surface (where the encapsulant contacts the substrate 106 or other components). These side surfaces 111 of the encapsulant 110 can be substantially perpendicular to those planes corresponding to the PCB 102, substrate 106, and/or memory layers 108. The protective material 112 may also be another self-tunable material, other than an FMHE material, that reduces its elastic modulus at high temperatures. Other suitable materials may include hybrid elastomers utilizing metal alloys other than fields metal. Although embodiments are not so limited, the protective material 112 can be formed (e.g., deposited) on the encapsulant 110 according to a semiconductor fabrication process such as chemical vapor deposition (CVD) in a semiconductor fabrication apparatus.

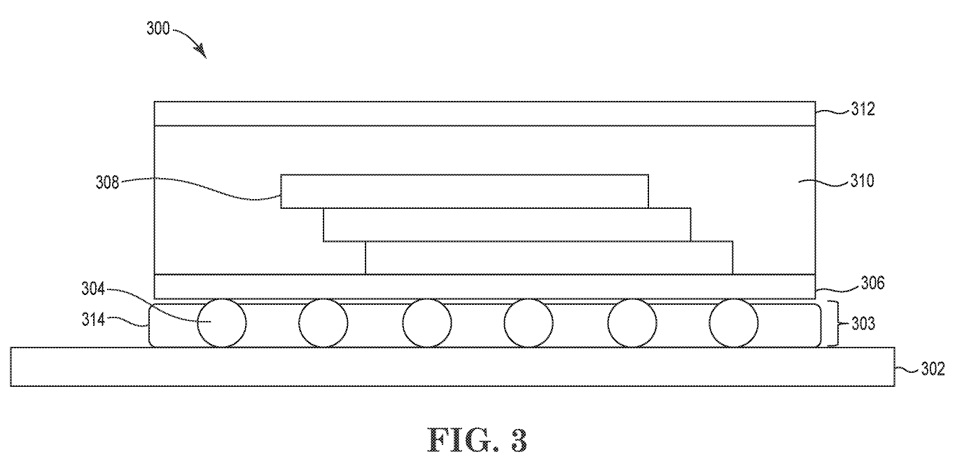

The substrate 106 (or the memory package 100) can be coupled to (e.g., mounted on) the PCB 102 via a number of interconnects 104-1, …, 104-6 (collectively referred to as “interconnects 104”). The interconnects 104 can be solder joints (e.g., functioning as metallic connections between the substrate 106 and the PCB 102 to provide electrical connectivity, mechanical support, etc.). In some embodiments, these solder joints 104 can be arranged in a ball grid array (BGA) configuration. As used herein, a layer (e.g., the layer 103 shown in FIG. 3) that is positioned between the substrate (e.g., the substrate 106) and the PCB (e.g., the PCB 102) and in which interconnects are located can be referred to as an “underfill layer” 103.

The protective material 112 may reduce the risk of cracks forming in the encapsulant 110 of the memory package 100. Components of the memory package 100 may expand when exposed to elevated temperatures. The components may experience a stress as a result of expanding, particularly if components are exposed to elevated temperatures rapidly, unevenly, or repeatedly. The stress experienced by the components of the memory package 100 may make the components of the memory package 100 more vulnerable to damage from a sudden shock or impulse. The encapsulant 110 in particular may be at increased risk of cracking or forming a defect. A defect in the encapsulant 110, even a small one, may result in failure of the memory package to function because a crack or defect in the encapsulant 110 can easily expand to the memory layers 108 or the substrate 106. The protective material 112 may prevent cracking of the encapsulant 110 by reducing the stress experienced by the encapsulant 110 at elevated temperatures. The stress experienced by the encapsulant may be reduced because the protective material 112 will self-tune the elastic modulus of the protective material 112 to allow the encapsulant 110 and other memory package 100 components to expand easier. The reduced stress may result in a higher durability during sudden shock or impulse for the memory package 100. The reduced stress may also reduce fatigue experienced by the memory package 100 as a result of repeated exposure to elevated temperatures.

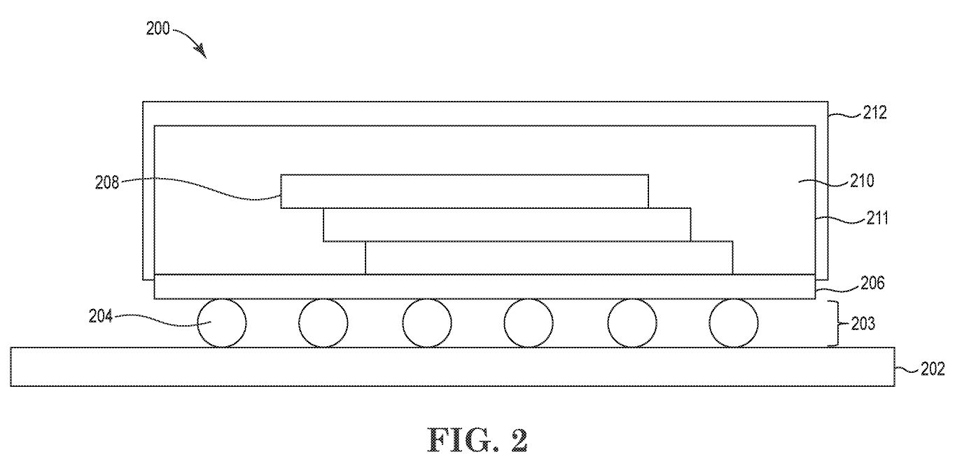

FIG. 2 illustrates another memory package 200 including a FMHE coating 212 on an encapsulant connected by interconnects 204 (e.g., solder joints) to a PCB 202 in accordance with a number of embodiments of the present disclosure. The memory package 200 (including the FMHE coating 212, encapsulant 210, memory layers 208, substrate 206), interconnects 204, and the PCB 202 can be analogous to the memory package 100 (including the FMHE coating 112, encapsulant 110, memory layers 108, substrate 106), interconnects 104, and the PCB 102 shown in FIG. 1.

FIG. 2 is generally analogous to FIG. 1 in that the memory layers 208 are surrounded by an encapsulant 210 that, in combination with the substrate 206, covers the entirety of the memory layers 208. FIG. 2 differs from FIG. 1 in that the encapsulant 210 is coated in a protective material 212 that covers all sides of the encapsulant 210, including those side surfaces 211 of the encapsulant 210 (e.g., side surfaces 211 that are substantially perpendicular to those planes corresponding to the PCB 202, substrate 206, and/or memory layers 208) that would have been exposed but for the structure of the encapsulant 210 shown in FIG. 2. Although embodiments are not so limited, FIG. 2 can be a depiction of a cross-sectional view of the memory package 200, the interconnects 204, and the PCB 202. As such, the encapsulant 210 and the memory layers 208 may not be visible due to the protective material 212 covering all sides of the encapsulant 210. The protective material 212 may be made up of an FMHE material or other suitable self-tuning material. The protective material 212 may resist thermal expansion of the memory package 200 components below a given temperature (e.g., a transition temperature). Above that given temperature the protective material 212 may have a reduced elastic modulus that allows the components to expand without experiencing the stress of expanding against a stiff material. The given temperature at which the protective material 212 switches between higher and lower elastic modulus may be around 80 degrees Celsius. The given temperature may also be around 60 degrees Celsius. The given temperature at which the protective material switches between higher and lower elastic modulus may be selected during manufacture by using a protective material 212 with the desired property. The ability to select a protective material 212 with a specific given temperature at which the elastic modulus self-tunes may be possible with a number of embodiments of this disclosure including the embodiment shown in FIG. 1.

The protective material 212 may provide better protection for the encapsulant 210 by surrounding the encapsulant 210 entirely, that is to say, all surfaces (e.g., every surface, each surface, etc.) of the encapsulant 210 not covered by the substrate 206 are coated by the protective material. Elevated temperatures may cause the memory package 200 to expand in all directions resulting in a stress experienced in multiple directions. The encapsulant 210 may be at risk of cracking on any surface due to this stress. Surrounding the encapsulant 210 entirely with the protective material 212 can reduce the stress experienced by the encapsulant on all sides.

FIG. 3 illustrates yet another example memory package 300 connected by a plurality of solder joints 304 to a PCB 302 including a FMHE coating 312 an encapsulant 310 and/or included in an underfill layer 303 in accordance with a number of embodiments of the present disclosure. The memory package 300 includes a substrate 306 with a number of memory layers 308 on it. The memory package 300 (including the FMHE coating 312, encapsulant 310, memory layers 308, substrate 306), interconnects 304, and the PCB 302 can be analogous to the memory package 100 (including the FMHE coating 112, encapsulant 110, memory layers 108, substrate 106), interconnects 104, and the PCB 102 shown in FIG. 1.

FIG. 3 is generally analogous to FIG. 1 except that an underfill layer 303 (e.g., situated between the printed circuit board 302 and the substrate 306 of the memory package 300) is filled with an underfill material 314. The underfill material 314 may contain a self-tuning material that may be an FMHE material. The underfill material 314 may reduce a stress on the solder joints 304 when the memory package is above a given temperature that may be around 60 degrees Celsius or around 80 degrees Celsius. The underfill material 314 may surround the solder joints 304.

The solder joints 304 may experience a stress from the memory package 300 expanding, particularly if the memory package 300 expands at a different rate or to a different extent than the PCB 302 they are attached to. The stress may cause the solder joints 304 to fatigue or fail resulting in the function of the memory package 300 being reduced or eliminated. An underfill material 314 including a self-tuning material may protect the solder joints 304 without providing more stress that could result from inhibiting expansion too much at elevated temperatures. The self-tuning material making up a part or all of the underfill material 314 may have a reduced elastic modulus at high temperatures allowing for expansion of the memory package 300 components including the substrate 306 and the solder joints 304 that the underfill material 314 may be in contact with.

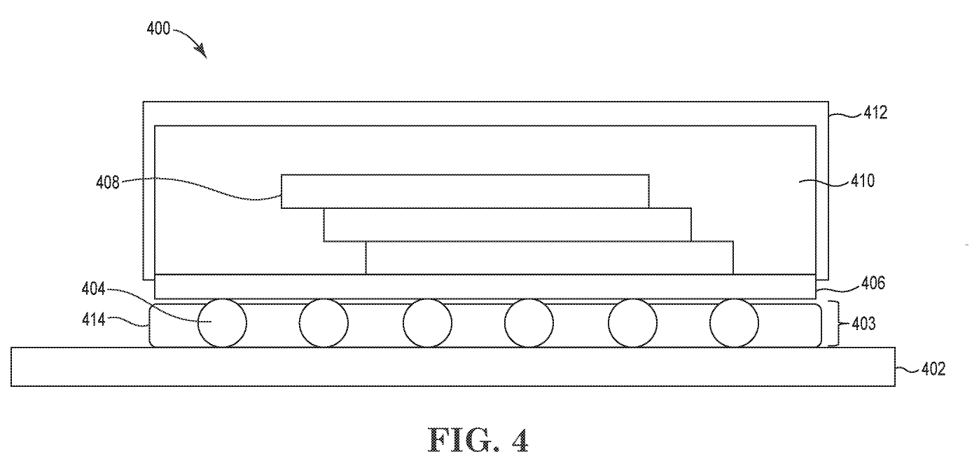

FIG. 4 illustrates yet another example memory package 400 connected by solder joints 404 to a PCB 402 including a FMHE 412 coating an encapsulant 410 and/or included in an underfill layer 403 in accordance with a number of embodiments of the present disclosure. The memory package 400 includes a substrate 406 with memory layers 408 on it. The memory package 400 (including the FMHE coating 412, encapsulant 410, memory layers 408, substrate 406), interconnects 404, and the PCB 402 can be analogous to the memory package 100 (including the FMHE coating 112, encapsulant 110, memory layers 108, substrate 106), interconnects 104, and the PCB 102 shown in FIG. 1.

FIG. 4 is generally analogous to FIG. 2 except that an underfill layer 403 (e.g., situated between the printed circuit board 402 and the substrate 406 of the memory package 400) is filled with an underfill material 414. The underfill material 414 may contain a self-tuning material that may be an FMHE material. The underfill material 414 may reduce a stress on the solder joints 404 when the memory package is above a given temperature that may be around 60 degrees Celsius or around 80 degrees Celsius. The underfill material 414 may surround the solder joints 404.

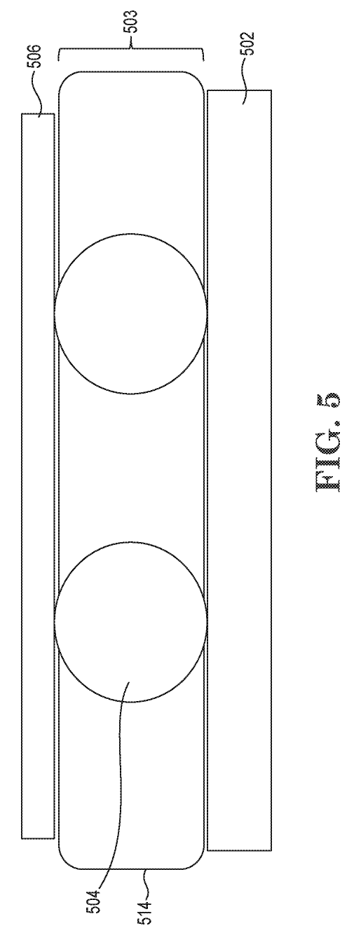

FIG. 5 is an illustration of an underfill layer 503 including a FMHE in accordance with a number of embodiments of the present disclosure. The underfill layer 503, substrate 506, interconnects 504, and the PCB 502 can be analogous to the underfill layer 103, substrate 106 interconnects 104, and the PCB 102 shown in FIG. 1. The substrate 506 may be part of a memory package that can be analogous to the memory package 100 of FIG. 1 but may also be analogous to a similar memory package that does not include a protective coating on the encapsulant.

The substrate 506 is connected to a PCB 502 by a plurality of solder joints 504. An underfill layer 503 (e.g., including the underfill material 514) is situated between the substrate 506 and the PCB 502. The underfill material 514 may be an FMHE material that protects the solder joints 504 from a stress when the substrate 506 and any other attached components reach temperatures above 60 or 80 degrees Celsius. The underfill material 514 may partially or completely fill a gap between the substrate 506 and the PCB 502 that is the thickness of the solder joints 504. The underfill material may surround the solder joints 504 as well as partially or completely filling the gap between the substrate 506 and the PCB 502.

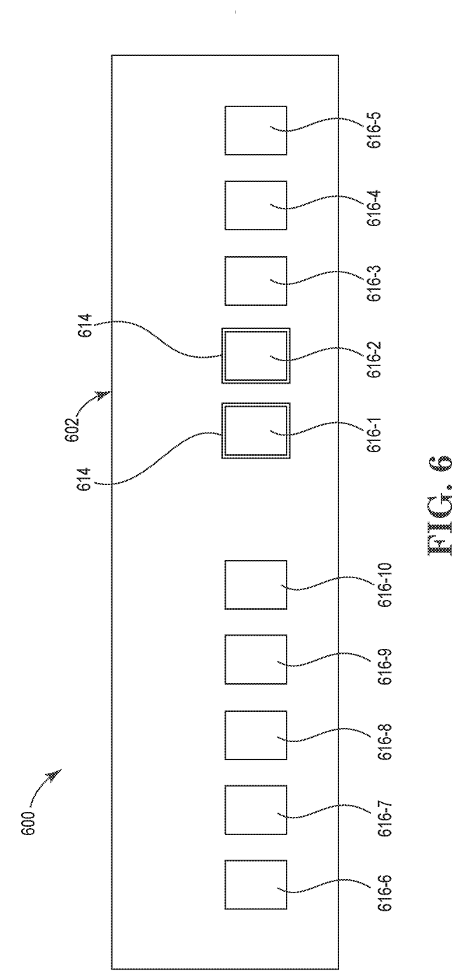

FIG. 6 illustrates a memory system 600 utilizing a number of memory packages 616-1, 616-2, … , 616-10, (collectively referred to as memory packages 616) in accordance with a number of embodiments of the present disclosure. While FIG. 6 depicts a memory system 600 with ten memory packages 616, embodiments are not limited to a specific number of memory packages 616.

A memory system 600 can be a memory module or a hybrid of a storage device and memory module, although embodiments are not so limited. Examples of memory modules include a dual in-line memory module (DIMM), a small outline DIMM (SO-DIMM), and various types of non-volatile dual in-line memory modules (NVDIMMs). The memory packages 616 can be a storage device, which can be and/or include a solid-state drive (SSD), a flash drive, a universal serial bus (USB) flash drive, an embedded Multi-Media Controller (eMMC) drive, a Universal Flash Storage (UFS) drive, a secure digital (SD) card, and a hard disk drive (HDD). Although not shown in FIG. 6 so as to not obfuscate the drawings, the memory system 600 can further include other circuitries, such as power management circuitry responsible for supplying regulating powers to the memory packages 616, special purpose circuitry in the form of an ASIC, FPGA, state machine, hardware processing device, and/or other logic circuitry that provides control and processing functionality within the memory system 600.

The memory system 600 may include a PCB 602 that the number of memory packages 616 may be attached to. Some of the memory packages 616 are coated in a protective material 614. While two memory packages 616 are shown to include the protective material 614, embodiments are not limited to a specific number of memory packages 616 with the protective coating 614, nor are the embodiments limited to a specific portion of memory packages 616 with the protective coating 614. A memory system 600 may include one memory package 616 with a protective coating 614, many memory packages 616 with the protective coating 614, or all memory packages included in the memory system 600 may include the protective coating 614. The protective material 614 may be a self-tuning material that has a lower elastic modulus at high temperatures, such as around 60 or 80 degrees Celsius, than at lower temperatures, such as at room temperature or around 20 degrees Celsius. The protective material 614 may be an FMHE material.

During normal use of a memory package, such as memory packages disclosed herein, electricity flows through the memory package to write data to memory cells in the memory layers and to read data stored in memory cells. As devices get faster, able to perform higher speed computations, they are required to access the memory more frequently, requiring more electricity. Increased electricity flowing through a memory device can cause more rapid increases in temperature and higher operating temperatures in general. A self-tunable compound such as a FMHE may reduce the stress experienced by components operating at high temperatures. Reduction in stress may allow the components to perform more reliably and for more uses resulting in an increased operational life. The increased reliability and operational life result from reduced fatigue on the components and a reduced vulnerability to shock and vibration that can result from stress on components.

A self-tunable compound may reduce stress by having a lower elastic modulus above a pre-set temperature. The temperature may be pre-set by selecting a materials with appropriate properties. For instance, a FMHE compound may reduce its elastic modulus at a specific temperature due to the concentration of field’s metal microparticles and spiked nickel microparticles in the hybrid elastomer. One mechanism by which a self-tunable material may reduce its elastic modulus is by reaching a specific temperature that will cause a phase change in microparticles such as fields metal microparticles. The specific temperature a self-tuning material may change its elastic modulus at may also be affected by using different materials for the elastomer and for the microparticles. For instance, the field’s metal microparticles may be an alloy of the metallic elements bismuth, tin, and indium. The ratios of the metals making up the alloy may be altered to affect the melting point of these microparticles. Other metals may also be included to affect the melting point of the alloy making up the microparticles. Other metals commonly used to make low melting point alloys, also called fusible alloys, are lead, cadmium, and gallium. These metals, in addition to bismuth, indium, and tin, may be used to create a hybrid elastomer with a self-tuning elastic modulus at a selected temperature. Other metals may also be used, though there may be other considerations such as toxicity, radioactivity, and scarcity that need to be considered. Some alloys names similar to Field’s metal such as harper’s metal, wood’s metal, and others, may be suitable for creating a self-tunable compound with different specific temperatures at which the elastic modulus changes.

Similar (e.g., the same) elements or components between different figures may be identified by the use of same or similar digits. As will be appreciated, elements shown in the various embodiments herein can be added, exchanged, and/or eliminated so as to provide a number of additional embodiments of the present disclosure. In addition, as will be appreciated, the proportion and the relative scale of the elements provided in the figures are intended to illustrate the embodiments of the present disclosure and should not be taken in a limiting sense.

As used herein, “a number of” or a “quantity of” something can refer to one or more of such things. For example, a number of or a quantity of memory layers can refer to one or more memory layers. A “plurality” of something intends two or more. As used herein, the term coating or coated refers to a material covering an area of another material. One material coating another material may be two materials that were formed together. Coating may also refer to a material placed upon or adhered to another material. Unless stated otherwise, where a single element is discussed, it is understood that all similar elements are referred to.

Although specific embodiments have been illustrated and described herein, those of ordinary skill in the art will appreciate that an arrangement calculated to achieve the same results can be substituted for the specific embodiments shown. This disclosure is intended to cover adaptations or variations of various embodiments of the present disclosure. It is to be understood that the above description has been made in an illustrative fashion, and not a restrictive one. Combination of the above embodiments, and other embodiments not specifically described herein will be apparent to those of skill in the art upon reviewing the above description. The scope of the various embodiments of the present disclosure includes other applications in which the above structures and methods are used. Therefore, the scope of various embodiments of the present disclosure should be determined with reference to the appended claims, along with the full range of equivalents to which such claims are entitled.

What is claimed is:

1. A memory package comprising:
a substrate;
a number of memory layers on the substrate;
an encapsulant surrounding the number of memory layers; and
a self-tunable compound capable of autonomously adjusting its elastic modulus in response to an external stimuli, the self-tunable compound coated on a first surface of the encapsulant opposite the substrate.

2. The memory package of claim 1, wherein the self-tunable compound surrounds the encapsulant entirely.

3. The memory package of claim 1, wherein the first surface of the encapsulant is opposite to a second surface of the encapsulant that is in contact with the substrate.

4. The memory package of claim 3, wherein one or more surface of the encapsulant that are substantially perpendicular to the first surface or the second surface are not coated with the self-tunable compound.

5. The memory package of claim 1, wherein the self-tunable compound is a field’s metal hybrid elastomer (FMHE).

6. The memory package of claim 5, wherein the FMHE contains indium.

7. The memory package of claim 5, wherein the FMHE contains spiked nickel particles.

8. The memory package of claim 1, wherein the self-tunable compound has a reduced elastic modulus when exposed to temperatures above 80 degrees Celsius.

9. The memory package of claim 1, further comprising:
a printed circuit board (PCB); and
an underfill layer on the PCB, the underfill layer on which the substrate is formed, wherein, the underfill layer is filled with a material comprising the self-tunable compound.

10. The memory package of claim 1, wherein the encapsulant corresponds to an epoxy mold compound (EMC).

11. An electronic device, comprising:
a memory package connected to circuitry of the electronic device, the memory package comprising:
an underfill layer;
a substrate on the underfill layer;
a number of memory layers on the substrate;
an encapsulant surrounding the memory layers; and
a field’s metal hybrid elastomer (FMHE) coating a first surface of the encapsulant opposite to the substrate and the underfill layer.

12. The electronic device of claim 11, wherein the FMHE is coating the entirety of the encapsulant.

13. The electronic device of claim 11, wherein the underfill layer further comprises one or more interconnects surrounded by a material comprising FMHE.

14. The electronic device of claim 13, further comprising a printed circuit board (PCB) on which the underfill layer is formed, wherein at least one of the one or more interconnects correspond to a solder joint that is in contact with the substrate and the PCB.

15. The electronic device of claim 11, wherein the FMHE comprises particles of spiked nickel and particles of an alloy comprising indium, bismuth, and tin dispersed in a polydimethylsiloxane (PDMS) matrix.

16. The electronic device of claim 11, wherein a mass ratio of the particles of spiked nickel to the PDMS matrix ranges from 0.5 to 3.

17. An apparatus for storing data, the apparatus comprising:
a substrate;
a number of memory layers on the substrate;
an encapsulant surrounding the number of memory layers; and
a protective material comprising low melting point solids dispersed in an elastomer matrix surrounding the encapsulant.

18. The apparatus of claim 17, further comprising:
a printed circuit board (PCB) connected to the substrate; and
an underfill layer between the PCB and the substrate, surrounding the connection, wherein the underfill layer comprises the protective material.

19. The apparatus of claim 17, wherein the low melting point solids corresponds to microparticles having respective diameters ranging from 10 micrometers to 20 micrometers.

20. The apparatus of claim 17, wherein the protective material is coating all surfaces of the encapsulant that are not in contact with the substrate.
